(19) United States
(12) Patent Application Publication
(10) Pub. No.: US 2025/0256956 A1
(43) Pub. Date: Aug. 14, 2025

(54) Method for Fabricating a Hermetically Sealed Contact and Hermetically Sealed Contact

(71) Applicant: Albert-Ludwigs-Universitat Freiburg, Freiburg (DE)

(72) Inventors: Muhannad Ghanam, Freiburg (DE); Frank Goldschmidtboing, Ortenberg (DE); Peter Woias, Freiburg (DE); Thomas Bilger, Buggingen (DE)

(73) Assignee: Albert-Ludwigs-Universitat Freiburg, Freiburg (DE)

(21) Appl. No.: 19/176,701

(22) Filed: Apr. 11, 2025

Related U.S. Application Data
(63) Continuation of application No. PCT/EP2023/077977, filed on Oct. 10, 2023.

(30) Foreign Application Priority Data
Oct. 11, 2022 (DE) 10 2022 126 328.2

(51) Int. Cl. B81C 1/00; B81B 3/00; G01P 15/08

(52) U.S. Cl. CPC B81C 1/00698; B81B 3/0086; G01P 15/0802; B81B 2201/0235; B81B 2203/0127; B81B 2203/0315; B81B 2203/04; B81B 2207/07; B81C 2201/0132; B81C 2201/0133; B81C 2203/035

(57) ABSTRACT

A method for creating a sensor includes generating in a housing a measurement cavity that is hermetically sealed, the measurement cavity is formed by an inside surface of a cover chip and an opposing top surface of a base chip. The inside surface has a membrane electrode and the top surface has a base electrode; the membrane electrode and the base electrode form a sensing capacitance. A first terminal contacts the membrane electrode and a second terminal contacts the base electrode. Each of the terminals is a horizontal metal layer that contacts a vertical metal layer of a vertical electrical connection through the housing. The horizontal metal layer and the vertical metal layer form a hermetically sealed contact. The method further includes forming a eutectic bond hermetically sealing the measurement cavity from an outside.

### CROSS-REFERENCE TO RELATED APPLICATIONS

This application is a continuation of PCT International Application No. PCT/EP2023/077977, filed on Oct. 10, 2023, which claims priority under 35 U.S.C. § 119 to German Patent Application No. 102022126328.2, filed on Oct. 11, 2022.

### FIELD OF THE INVENTION

The invention relates to a method for fabricating a hermetically sealed contact between a vertical electric connection (also referred to as “vertical interconnect access”, VIA) through a cover chip and a terminal on a base chip, a method for making an acceleration sensor, and a hermetically sealed contact.

### BACKGROUND

As used herein, a hermetic seal is any type of sealing that makes a given object airtight, i.e. preventing the passage of air, oxygen, or other gases. Hermetic seals are essential to the correct and safe functionality of many electronic and healthcare products. Used technically, a hermetic seal is stated in conjunction with a specific test method and conditions of use, for example the use of a sensor. Standard test methods are available for measuring sealing parameters, such as the moisture vapor transmission rate, oxygen transmission rate, helium transmission rate, etc.

As used herein, a VIA is an electrical connection between electrically conducting layers, e.g. metal layers comprising copper, gold, or aluminum, formed on a chip. For example, a VIA is a hole that goes through two or more adjacent layers; the hole is plated with a metal, which forms an electrical connection through the insulation that separates the conducting layers. As used herein, a chip is a small flat piece of semiconductor material.

As used herein, a terminal is the point at which a conductor from a component, device or network comes to an end. Terminal as used herein refers to an electrical connector at this endpoint, acting as the interface to a conductor and creating a point where external circuits can be connected. In other words, a terminal may be the end of an electric connection.

It is known that a VIA through a chip, such as a through-silicon via (TSV) or through-chip via, is fabricated by filling a thin hole in a chip, the thin hole having a diameter of up to 1 μm and usually a depth of up to 250 μm. Having these small diameters allows to fill the complete hole, and thus, the TSV is usually hermetically sealed. The manufacturing process often requires complex machining and treatments, such as wafer thinning, polishing, high-temperature diffusion processes, etc.

One of the most-known methods for structuring TSVs is to fill the hole with copper by electroplating. However, there are concerns about the reliability of TSVs. It has been proven that thermal cycling, such as annealing, can induce mechanical failure in TSVs. The differences in thermal expansion coefficients between Cu and the Si wafer result in significant mechanical stress, which has an impact on device performance. Cu extrusions induced by thermal treatments can cause both TSVs and adjacent interconnect structures to fail. Further, a TSV is either manufactured before, during, or after fabricating individual components, e.g. transistors or metal layers for contacting. However, the process technologies are expensive and time consuming. Currently, TSVs are mostly applied to create 3D packages and 3D integrated circuits. Alternatively, an epoxy may be used to fill a larger diameter through hole, however, an epoxy may not hermetically sealing at elevated temperatures.

Despite the advanced development of sensors, there is still a great need for Micro-Electro-Mechanical Systems (MEMS) solutions for sensors, such as absolute pressure sensors, force sensors, and acceleration sensors operating at high temperatures. The requirements for such applications as biomedical systems, industrial process control, aerospace, petrochemical, and monitoring combustion processes in power generation systems include high operating temperature, high sensitivity, long-term signal stability and mechanical stability, as well as low power consumption, miniaturization and significant reduction in the temperature dependence of the sensor signal. Some of the best known MEMS sensors are piezoresistive and capacitive sensors.

Piezoresistive sensors are known for their high linearity, small dimensions and ease of signal processing. Since piezoresistive sensors are stress-sensitive, the output signal can be affected by mechanical stress or thermally induced stress due to a mismatch between the sensor and its packaging material, and the output signal exhibits a strong temperature dependence due to leakage at the insulating pn junctions. For example, piezoresistive absolute sensors for different measuring ranges can operate at temperature of up to 150°. A nonlinearity of 0.02% full scale (FS) and a temperature coefficient of the zero point of −0.6% FS/100° C. are obtained. An all-SiC piezoresistive absolute sensor is measured with a nonlinearity of 0.034% FS and a temperature sensitivity of −0.134% FS/° C. at 250° C.

Capacitive sensors are characterized by high pressure sensitivity and low temperature drift, low power consumption and high g-shock resistance. A single crystal 3C—SiC capacitive pressure sensor is reported for high temperature sensing applications. In the linear range the measurements shows a linearity of 2.1% and a sensitivity of 7.7 fF/torr at 400° C.

Compared to piezoresistive pressure sensors, capacitive sensors are more sensitive and have a lower temperature drift. However, their parasitic and stray capacitances make the measurement of capacitance and the linearization of the output signal more difficult. The manufacturing processes of capacitive sensors typically require complex equipment, high process temperatures and critical pretreatments which are necessary for packaging methods such as anodic bonding or silicon-silicon direct boding.

Further, sensors, e.g. acceleration sensors, may require a hermetically-sealed cavity as a reference chamber. Additionally or alternatively, in some cases the sensor must be protected from the measurement medium. Anodic bonding, silicon-silicon direct bonding and glass frits bonding are the main methods used to produce the sealed cavity. Such packaging methods require complex equipment, high process temperatures, high voltage and critical pretreatments. In addition, they complicate the electrical connection of the capacitive sensor electrodes to the contact terminals, which has become a major challenge for the design and manufacturing of these sensors.

In order for a capacitive sensor to be able to operate in high temperature ranges, two effects must be considered: Temperature dependent changes in the permittivity of the dielectric material and the thermal stress at the interfaces between different components of the sensor.

### SUMMARY

A method for creating a sensor includes generating in a housing a measurement cavity that is hermetically sealed, the measurement cavity is formed by an inside surface of a cover chip and an opposing top surface of a base chip. The inside surface has a membrane electrode and the top surface has a base electrode; the membrane electrode and the base electrode form a sensing capacitance. A first terminal contacts the membrane electrode and a second terminal contacts the base electrode. Each of the terminals is a horizontal metal layer that contacts a vertical metal layer of a vertical electrical connection through the housing. The horizontal metal layer and the vertical metal layer form a hermetically sealed contact. The method further includes forming a eutectic bond hermetically sealing the measurement cavity from an outside.

### BRIEF DESCRIPTION OF THE DRAWINGS

The invention will now be described by way of example with reference to the accompanying Figures, of which:

FIG. 1 is a schematic of a cover chip after an etching step;

FIG. 2 is a schematic of a cover chip after a pre-conditioning step;

FIG. 3 is a schematic of a cover chip after a depositing step;

FIG. 4 is a schematic of a base chip after an etching step;

FIG. 5 is a schematic of a base chip after a pre-conditioning step;

FIG. 6 is a schematic of a base chip after a depositing step;

FIG. 7 is a schematic of a sensor after a bonding step;

FIG. 8 is a further view of the base chip of FIG. 6;

FIG. 9 is an equivalent circuit diagram of a sensor as shown in FIG. 7;

FIG. 10 is a further equivalent circuit diagram of a sensor as shown in FIG. 7;

FIG. 11 is a schematic of a further alternative for FIG. 1;

FIG. 12 is a schematic of a further alternative for FIG. 1;

FIG. 13 is an example schematic of an acceleration sensor; and

FIG. 14 is a further example schematic of an acceleration sensor.

### DETAILED DESCRIPTION

According to a first general example, the present disclosure relates to a bonded connection between a vertical metal layer of a VIA of a cover chip to a horizontal metal layer of a terminal of a base chip. The inventors found out that a thermocompression bonding hermetically seals the contact between the VIA and the terminal. Thus, an economic process for a TSV can be provided that is particularly advantageous for sensor applications.

The metal layers can comprise gold, aluminum, or copper which is advantageous for thermocompression bonding. Notably, gold is usually not used for TSVs, because in the 3D chip integration gold would change the band gap of components such as transistors.

A first example of the present description relates to a method for fabricating a hermetically sealed contact between a vertical electric connection (VIA) through a cover chip and a terminal on a base chip. The base chip and the cover chip are separate from each other. For example, each of the base chip and the cover chip may be arranged on a wafer. Thus, a plurality of hermetically sealing contacts can be fabricated in parallel by executing the following steps on wafer level. Further, the terminal on the base chip can for example be used for electrically contacting an electrode formed in a measurement cavity.

In a first step according to the first example, a vertical through hole is etched through the cover chip for forming an etched through hole surface connecting an outside opening and an opposing inside opening, the inside opening facing the terminal on the base chip.

The through hole may be etched by dry etching or wet etching process. Dry etching refers to the removal of material, typically a masked pattern of semiconductor material, by exposing the material to a bombardment of ions (usually a plasma of reactive gases such as fluorocarbons, oxygen, chlorine, boron trichloride; sometimes with addition of nitrogen, argon, helium and other gases) that dislodge portions of the material from the exposed surface. Alternatively, by wet etching the first etching processes uses liquid-phase (“wet”) etchants.

By the etching, the through hole is generated in the cover chip. The cover chip has an outside surface and an opposing inside surface. The outside surface, from where the through hole can be etched, comprises after the etching the outside opening. The outside opening may be used to place an outside terminal, the outside terminal for connecting to an evaluation unit or other electronics. Further, the through hole opens to an inside opening comprised on the inside surface. The inside opening opens for example to a measurement cavity. Thus, by the through hole it is possible to provide electrical contacts from the outside, i.e. the evaluation unit, to the measurement cavity. The open through hole, however, is not hermetically sealed.

The first example further comprises the step of pre-conditioning the etched through hole surface for generating a clean, in particular electrically insulating, through hole surface and pre-conditioning a contacting region of the base chip for generating a clean, in particular electrically insulating, contacting region. The through hole surface is the surface facing the through hole. The contact region is formed on the base chip.

Pre-condition enables for depositing a material on the through hole surface and the contact region. Thus, the pre-conditioning improves the thermocompression bonding process. Notably, after the pre-condition step, the electrically insulating through hole surface does not close the open through hole. In other words, the pre-conditioned through hole is not hermetically sealing.

The first example further comprises the step of depositing a vertical metal layer on the electrically insulating through hole surface for generating the VIA through the cover chip and depositing a horizontal metal layer on the electrically insulating contacting region for generating the terminal on the base chip.

The metal films can be deposited by evaporation, sputtering, electroplating, or the like. Evaporation and sputtering, producing high quality films with limited impurities, are slow and hence used for μm and sub-μm layer thicknesses. The electroplating is commonly used for thicker films and needs careful monitoring and control of the film roughness and the layer purity.

The vertical metal layer extends in a direction for closing the opening, i.e. normal to the surface of the through hole. In other words, after the metal deposition of the metal film, the through hole can be closed. Notably, the vertical metal layer does not necessarily close the open through hole. In other words, the metal deposited through hole is not necessarily hermetically sealing.

The horizontal metal layer extends in a direction normal to the surface of the base chip. In other words, the horizontal metal layer is arranged to be perpendicular to the vertical metal layer, when the base chip is aligned with the cover chip.

Finally, the first example comprises the step of thermocompression bonding the vertical metal layer of the VIA to the horizontal metal layer of the terminal for forming a bonded connection, the bonded connection hermetically sealing the contact between the VIA and the terminal.

Thermocompression bonding describes a chip or wafer bonding technique and is also referred to as diffusion bonding, pressure joining, thermocompression welding or solid-state welding. Two metals, e.g. gold (Au)-gold (Au), are brought into atomic contact by applying force and heat simultaneously. The diffusion requires atomic contact between the surfaces due to the atomic motion. The atoms migrate from one crystal lattice to the other one based on crystal lattice vibration. This atomic interaction sticks the interface together.

Thermocompression bonding enables internal structure protecting device packages and direct electrical interconnect structures without additional steps beside the surface mounting process. The most established materials for thermocompression bonding are copper (Cu), gold (Au) and aluminum (Al) because of their high diffusion rates. In addition, aluminum and copper are relatively soft metals with good ductility.

Notably, the vertical metal layer of the VIA protrudes in the direction normal to the through hole, i.e. the vertical metal layer has a horizontal component forming a surface parallel to the horizontal metal layer of the terminal, when the base chip and the cover chip are aligned for thermocompression bonding. At least the horizontal component and the horizontal metal layer are bonded.

In an embodiment, the cover chip comprises at the inner surface a bonding region that comprises an opposing metal layer for bonding with the horizontal metal layer. The opposing metal layer can formed as the horizontal metal layer. Thus, the region forming the bond connection can be increased in a horizontal dimension.

A first aspect of the present description relates to a hermetically sealed contact between a vertical electric connection, VIA, through a cover chip and a terminal on a base chip.

The contact comprises a cover chip and a base chip, wherein the cover chip comprises a vertical through hole with a through hole surface, the through hole opening through the cover chip, wherein the through hole connects an outside opening and an opposing inside opening, the inside opening facing the terminal on the base chip.

Further, the contact can comprise an electrically insulating through hole layer formed on the through hole surface and an electrically insulating contacting surface formed on a contacting region of the base chip.

Further, the contact comprises a vertical metal layer on the electrically insulating through hole layer and a horizontal metal layer on the electrically insulating contacting layer forming the terminal on the base chip.

Further, the contact comprises a bonded connection, the bonded connection hermetically sealing the contact between the VIA and the terminal.

In particular, the contact according to the aspect can be formed by the method according to the first example. Structures described with reference to the above first example and the following examples can define the contact according to the first aspect.

According to a second example, in addition to the first example and/or the first aspect, the vertical through hole is formed by an anisotropic wet etch process, for forming the through hole having the shape of a frustum, and/or by a dry etch process for forming the through hole having the shape of a prism.

As used herein a frustum is the portion of an object (e.g. a pyramid or a cone) that lies between one or two parallel planes cutting it. The base faces are polygonal, the side faces are trapezoidal. A right frustum is a right pyramid or a right cone truncated perpendicularly to its axis. A pyramid is a polyhedron formed by connecting a polygonal base and a point, called the apex. Each base edge and apex form a triangle, called a lateral face. It is a conic solid with polygonal base. A pyramid with an n-sided base has n+1 vertices, n+1 faces, and 2n edges.

As used herein, a prism is a polyhedron comprising an n-sided polygon base, a second base which is a translated copy (rigidly moved without rotation) of the first, and n other faces, necessarily all parallelograms, joining corresponding sides of the two bases.

By using such etching processes, a suitable height profile (etch profile) can be realized for the through hole. Thus, mismatches during the thermocompression process can be eliminated and the electrode spacing according to the design of the application, e.g. a sensor application or alternative applications, can be adjusted.

According to a third example, in addition to the first to second example and/or the first aspect, an incircle of the outside opening has a diameter of greater than or equal to 70 μm and/or a diameter of less than or equal to 1000 μm in the horizontal dimension. Even more advantageously, the incircle of the outside opening has a diameter of greater than or equal to 250 μm and/or a diameter of less than or equal to 500 μm in the horizontal dimension.

As used herein, the incircle or inscribed circle of is the largest circle that is contained in a circumscribing polygon; it touches (is tangent to) the sides.

Such an arrangement ensures a sufficient large structure for thermocompression process.

In particular, using only wet etching allows for an outside opening having a diameter of greater than or equal to 250 μm and/or a diameter of less than or equal to 1000 μm in the horizontal dimension. The resulting inside opening has in this case a diameter of greater than or equal to 5 μm and less than or equal to 200 μm.

In particular, using only dry etching allows for an outside opening having a diameter of greater than or equal to 70 μm and/or a diameter of less than or equal to 500 μm in the horizontal dimension. The resulting inside opening has in this case a diameter of greater than or equal to 20 μm and less than or equal to 300 μm.

According to a fourth example, in addition to the first to third example and/or the first aspect, a surrounding region abutting to the outside opening has a thickness in the vertical dimension of greater equal 150 μm and/or less equal 800 μm.

Such an arrangement allows that the residual thickness of the chip, e.g. the silicon chip or wafer, in the area of the opening is such that the area has sufficient stability for the following bonding process (i.e. the chip or the wafer in this region has to be greater than 150 μm). Further, a thickness of less than 800 μm ensures that the vertical metal layer covers securely the surface of through hole in the metallization step.

According to a fifth example, in addition to the first to fourth example and/or the first aspect, the pre-conditioning step comprises a step of passivating a base material of at least one of the cover chip and the base chip. Advantageously, the base material comprises or consists of silicon that is passivated by oxidation. Alternatively, the base material can comprise silicon carbide and silicon nitrides with or without silicon oxides as passivation.

Passivation allows for preparing the surface, e.g. the surface having sufficient smoothness. Thus, further layers, e.g. an adhesive layer or a diffusion barrier layer, can be added. Further, the metal layer deposited on the passivated layer forms may for a first capacitor plate. A second capacitor plate can be formed by the silicon on the other side of the passivated layer. Thus, a parasitic capacitance is formed. This parasitic capacitance is in general a disadvantage. However, if the base chip and the cover chip comprise the same material, in particular conducting silicon, the base and the cover together form a Faraday cage. Thus, it is possible to ground this parasitic capacitance. Further, silicon as a material has the advantage of being high temperature and time stable.

According to a sixth example, in addition to the first to fifth example and/or the first aspect, wherein each of the vertical metal layer and the horizontal metal layer comprise a same metal. In particular, the vertical metal layer and the horizontal metal layer can consist of the same metal. In an embodiment, at least one of the vertical metal layer and the horizontal metal layer comprise at least one of gold, aluminum, and copper.

Using the same material for the metal layers improves the diffusion process, i.e. the exchange of material between the two metal layers for forming the thermocompression bond. In particular, Al, Au, and Cu have high diffusion rates.

Notably, the horizontal metal layer forms the terminal. The terminal may be part of a terminal structure. The terminal comprises the same material as the vertical metal layer. Other parts of the terminal structure may comprise the same metal or other metals.

According to a seventh example, in addition to the first to sixth example and/or the first aspect, the step of depositing the vertical metal layer and/or depositing the horizontal metal layer comprises additionally depositing at least one of an adhesive layer and a diffusion barrier layer.

According to an eighth example, in addition to the seventh example, a vertical adhesive layer is formed on the electrically insulating through hole surface, a vertical diffusion barrier layer is formed on the vertical adhesive layer, and the vertical metal layer is formed on the vertical diffusion barrier layer, and/or wherein a horizontal adhesive layer is formed on the electrically insulating contacting region, a horizontal diffusion barrier layer is formed on the horizontal adhesive layer, and the horizontal metal layer is formed on the horizontal diffusion barrier layer.

According to a ninth example, in addition to the seventh or eighth example, the adhesive layer comprises at least one of titanium, chromium, titanium tungsten, titanium nitrides, nickel, tantalum, niobium and metals from the platinum group, and/or wherein the diffusion barrier comprises at least one of titanium, chromium, titanium tungsten, titanium nitrides, nickel, tantalum, niobium and metals from the platinum group.

The materials used for the adhesive layer and the diffusion barrier layer are particularly advantageous for a thermocompression bonding process.

According to a tenth example, in addition to the first to ninth example and/or the first aspect, the method further comprises a microfabrication step for fabricating a recess in the cover chip, the recess being horizontally spaced from the through hole and extending in the vertical dimension to form a membrane in the cover chip. The membrane enables to use the base chip as a capacitive sensor, e.g. a force sensor, a pressure sensor, or an acceleration sensor.

According to an eleventh example, in addition to the tenth example, the recess is comprised on an outside surface, the outside surface comprises the outside opening of the through hole. This is a particular efficient manufacturing process, because one surface is fabricated for generating a cover of a sensor, which uses hermetically sealed VIAs. Alternatively, the recess can be comprised on an outside surface of the base chip, which is particularly advantageous for isolating the medium from electrical contact. Advantageously, the membrane has a thickness of greater equal 10 μm and/or less equal 800 μm.

According to a twelfth example, in addition to the tenth or eleventh example, by the microfabrication step a test mass is formed on the membrane, the test mass vertically protruding from the membrane. Advantageously, the test mass is comprised on an outside surface of the cover chip, the outside surface comprises the outside opening of the through hole, the test mass for transducing an external force to the membrane. Even more advantageously, the test mass is surrounded by the recess.

This solution enables a force sensor. In case of an acceleration sensor, the test mass may be referred to as a proof mass or a seismic mass. This combination of test mass and a VIA is particularly important for a force sensor which can be operated at elevated temperatures.

According to a thirteenth example, in addition to any of the tenth to twelfth example, the method may further comprises a microfabrication step of forming on an inside surface of the cover chip a deepening recessing in the vertical dimension, the inside surface comprises the inside opening. Advantageously, the microfabrication step is part of the etching step. The deepening enables various effects for a sensor, for example a thin membrane, reducing the thickness for the via, and compensation of differences in the vertical dimension of the contacts in the cover chip.

According to a fourteenth example, in addition to the thirteenth example, the deepening comprises at least one of a membrane deepening, a through-hole deepening, and an edge deepening, wherein the membrane deepening is horizontally spaced apart from the inside opening to form a membrane in the cover chip, the through-hole deepening is horizontally aligned with the inside opening to reduce a thickness of the cover chip in a region of the VIA, and the edge deepening is surrounding the inside opening, the edge deepening for bonding the cover chip to the base chip. In particular, the solution of a combination of the membrane deepening and the through-hole deepening is a cavity that enables forming the measurement cavity when bonding the base chip to the cover chip.

According to a fifteenth example, in addition to the first to fourteenth example and/or the first aspect, the method further comprising a microfabrication step for fabricating in a top surface of the base chip a vertically protruding protrusion for forming a measurement cavity that is hermetically sealed from the outside opening by the bonded connection, the top surface of the base chip comprising the terminal. Advantageously, the microfabrication step is part of the etching step. Even more advantageously, the protrusion comprises at least one of a contact pin, the contact pin comprising the terminal, and a frame surrounding the terminal, the frame for bonding the base chip to the cover chip for forming the measurement cavity.

As used herein, a pin is a device used for fastening objects or material together, i.e. the base chip the cover chip.

A protrusion enables to form a cavity for a sensor having a hermetically sealed volume. The contact pin enables a particular strong bond between terminal and VIA, because the distance in a vertical dimension of the horizontal metal layer and the vertical metal layer is reduced.

According to a second aspect, the present disclosure relates to a method for generating a sensor, e.g. a force sensor, a pressure sensor, or an acceleration sensor. The method comprising the steps of:
generating in a housing a hermetically sealed measurement cavity, wherein the measurement cavity comprises an inside surface of a cover chip and an opposing top surface of a base chip, the inside surface comprising a membrane electrode and the top surface comprising a base electrode, the membrane electrode and the base electrode for forming a sensing capacitance;
contacting the membrane electrode by a first terminal,
contacting the base electrode by a second terminal,
wherein the first terminal is a first horizontal metal layer and contacts a first vertical metal layer of a first VIA through the housing, wherein first horizontal metal layer and the first vertical metal layer forming a first hermetically sealed contact according to any of the first to fifteenth example and/or the first aspect.

The first terminal enables to contact the internal of the measurement cavity.

Additionally or alternatively, the sensor according to the second aspect comprises the second terminal, wherein the second terminal is a second horizontal metal layer and contacts a second vertical metal layer of a second VIA through the housing, wherein the second horizontal metal layer and the second vertical metal layer forming a second hermetically sealed contact according to any of the first to fifteenth example and/or the first aspect.

A second terminal enables to contact each of two capacitor plates of a capacitor arranged in the measurement cavity. Thus, the influences of parasitic capacitances can be reduce. Alternatively. One capacitor plate may be contacted by the VIA, the second capacitor plate can be formed by the conducting housing. This has the disadvantage that the parasitic capacitance is included in the measurement signal and is also measured.

For a detailed description of the sealed contact is referred to the above description.

Additionally, the method for fabricating the sensor according to the second aspect comprises a step of eutectic bonding an edge region arranged on the inside surface of the cover chip and surrounding the membrane electrode to a frame region arranged on the top surface of the base chip and surrounding the base electrode for forming an eutectic bond, the eutectic bond hermetically sealing the measurement cavity from the outside.

Eutectic bonding, also referred to as eutectic soldering, describes a wafer bonding technique with an intermediate metal layer that can produce a eutectic system. Those eutectic metals are alloys that transform directly from solid to liquid state, or vice versa from liquid to solid state, at a specific composition and temperature without passing a two-phase equilibrium, i.e. liquid and solid state. The fact that the eutectic temperature can be much lower than the melting temperature of the two or more pure elements can be important in eutectic bonding. Eutectic alloys are deposited for example by sputtering, dual source evaporation or electroplating. They can also be formed by diffusion reactions of pure materials and subsequently melting of the eutectic composition.

Eutectic bonding is based on the ability of for example silicon (Si) to alloy with numerous metals and form a eutectic system. The most established eutectic formations are Si with gold (Au) or with aluminum (Al).

According to a sixteenth example, in addition to the second aspect, the method further comprises the steps of:
pre-conditioning a membrane measurement region arranged on the inside surface of the cover chip for generating a clean, in particular electrically insulating, membrane measurement surface and pre-conditioning a base measurement region arranged on the top surface of the base chip for generating a clean, in particular electrically insulating, base measurement surface; and
depositing a membrane metal layer on the electrically insulating membrane measurement surface for generating a membrane electrode of the sensor and depositing a base metal layer on the electrically insulating base measurement surface for generating a base electrode.

Further, the method may also comprise the step of depositing an adhesion and/or a diffusion layer to be arranged between the electrically insulating surfaces and a subsequently deposited metal layer.

The membrane metal layer and the base metal layer may form a capacitance. Thus, a sensor can be realized.

Advantageously, depositing a membrane metal layer is comprised by the step of depositing a vertical metal layer forming the VIA and/or wherein depositing a base metal layer is comprised in the step of depositing a horizontal metal layer forming the terminal.

According to a seventeenth example, in addition to the sixteenth example and/or the second aspect, the cover chip and the bottom chip comprise or consist of a conducting material thereby forming a Faraday cage for protecting the sensing capacitance against external interference.

Thus, the effect of parasitic capacitances can be reduced.

According to an eighteenth example, in addition to the sixteenth to seventeenth example and/or the second aspect, the cover chip comprises at least one of the first and second VIA.

A third aspect, the method of the description relates to a method for generating an acceleration sensor, the method comprising the steps of:
generating in a housing a hermetically sealed measurement cavity, wherein the measurement cavity comprises first surface and an opposing second surface, the first surface comprising a first electrode and the second surface comprising a second electrode, the first electrode and the second electrode for forming a sensing capacitance;
contacting the sensing capacitance by a first terminal, advantageously the sensing capacitance is connected by two terminals,
wherein the housing comprises a cover chip, an intermediate chip, and a bottom chip,
eutectic bonding the cover chip to the intermediate chip by a first eutectic bond
eutectic bonding the intermediate chip to the base chip by a second eutectic bond, wherein the cover chip, the intermediate chip, and the bottom chip comprise or consist of a conducting material thereby forming a Faraday cage for protecting the sensing capacitance against external interference.

In other words, the acceleration sensor is formed by two eutectic bonding steps.

Further, the sensor according to the third aspect comprises the intermediate chip, wherein the intermediate chip comprises a deflectable seismic mass for changing the capacitance of the sensing capacitance.

In particular, the seismic mass deflects under the influence of external accelerations from its neutral position. This deflection is measured in an analog or digital manner. Most commonly, the capacitance between a set of fixed beams or a set of beams attached to the seismic mass is measured.

A fourth aspect of the disclosure relates to a method for generating an acceleration sensor, the method comprising the steps of: generating in a housing a hermetically sealed measurement cavity, wherein the measurement cavity comprises an inside surface of a cover chip comprising a membrane and an opposing top surface of a base chip, the inside surface comprising a membrane electrode formed on the membrane and the top surface comprising a base electrode, the membrane electrode and the base electrode for forming a sensing capacitance; contacting the membrane electrode by a first terminal, contacting the base electrode by a second terminal, eutectic bonding a first edge region arranged on the inside surface of the cover chip and surrounding the membrane to a frame region arranged on the top surface of the base chip and surrounding the base electrode for forming an eutectic bond, the eutectic bond hermetically sealing the measurement cavity from the outside, and eutectic bonding a second edge region arranged on an outside surface of the cover chip, the outside surface opposing the inside surface, and surrounding the membrane to a protecting chip for forming a hermetically sealed protecting cavity, wherein the membrane comprises a deflectable seismic mass for changing the capacitance of the sensing capacitance.

A fifth aspect of the disclosure relates to a method for generating an acceleration sensor, the method comprising the steps of: generating in a housing a hermetically sealed measurement cavity, wherein the measurement cavity comprises a first inside surface of a cover chip and an opposing top surface of an intermediate chip, and a second inside surface of a base chip and an opposing bottom surface of the intermediate chip; the first inside surface comprising a first inside electrode and the top surface comprising a first intermediate electrode, the first inside electrode and the first intermediate electrode for forming a first sensing capacitance; the second inside surface comprising a second inside electrode and the bottom surface comprising a second intermediate electrode, the second inside electrode and the second intermediate electrode for forming a second sensing capacitance; contacting the first sensing capacitance by a first terminal, advantageously the first sensing capacitance is connected by two terminals, contacting the second sensing capacitance by a second terminal, advantageously the second sensing capacitance is connected by two terminals, eutectic bonding a first edge region arranged on the first inside surface of the cover chip and surrounding the first inside electrode to a first frame region arranged on the top surface of the intermediate chip and surrounding the first intermediate electrode for forming a first eutectic bond, eutectic bonding a second edge region arranged on the second inside surface of the base chip and surrounding the second inside electrode to a second frame region arranged on the bottom surface of the intermediate chip and surrounding the second intermediate electrode for forming a second eutectic bond, the first and second eutectic bond hermetically sealing the measurement cavity from the outside, wherein the intermediate chip comprises a tongue holding a deflectable seismic mass between the top electrode and the bottom electrode for changing the capacitance of the first and second sensing capacitance.

According to a twentieth example, in addition to the fourth and fifth aspect, the first terminal is connected to a first VIA forming a first hermetically sealed contact and/or the second terminal is connected to a second VIA forming a second hermetically sealed contact, the method for fabricating the hermetically sealed contact comprises the steps of: etching a vertical through hole through the cover chip for forming an etched through hole surface connecting an outside opening and an opposing inside opening, the inside opening facing the first and/or second terminal on the base chip; pre-conditioning the etched through hole surface for generating an electrically insulating through hole surface and pre-conditioning a contacting region of the base chip for generating an electrically insulating contacting region; depositing a vertical metal layer on the electrically insulating through hole surface for generating the VIA through the cover chip and depositing a horizontal metal layer on the electrically insulating contacting region for generating the first and/or second terminal on the base chip; thermocompression bonding the vertical metal layer of the VIA to the horizontal metal layer of the first and/or second terminal for forming a bonded connection, the bonded connection hermetically sealing the contact between the VIA and the terminal.

For a detailed description is referred to the above description of examples 1 to 20 and aspects 1 to 3, which can be used to explain further details.

According to a twenty-first example, in addition to each of the fourth and fifth aspect and the twentieth example, an incircle of the outside opening has a diameter of greater than or equal to 70 μm and/or a diameter of less than or equal to 1000 μm in the horizontal dimension, in an embodiment a diameter of greater than or equal to 250 μm and/or a diameter of less than or equal to 500 μm in the horizontal dimension.

According to a twenty-second example, in addition to each of the fourth and fifth aspect and the twentieth to twenty-first example, a surrounding region abutting to the outside opening has a thickness in the vertical dimension of greater equal 150 μm and/or less equal 800 μm.

According to a twenty-third example, in addition to each of the fourth and fifth aspect and the twentieth to twenty-second example, the pre-conditioning step comprises passivating a base material of at least one of the cover chip, the base chip, the intermediate chip, and the protecting chip, in an embodiment wherein the base material comprises or consists of silicon that is passivated by oxidation.

According to a twenty-third example, in addition to each of the fourth and fifth aspect and the twentieth to twenty-third example, each of the vertical metal layer and the horizontal metal layer comprise a same metal, in an embodiment wherein the vertical metal layer and the horizontal metal layer comprise at least one of gold, aluminum, and copper.

According to a twenty-fourth example, in addition to each of the fourth aspect and the twentieth to twenty-third example, the method further comprises a microfabrication step for fabricating a recess in the cover chip, the recess being horizontally spaced from the through hole and extending in the vertical dimension to form a membrane in the cover chip, optionally wherein the microfabrication step is part of the etching step.

According to a twenty-fifth example, in addition to the twenty-fourth example, the recess is comprised on an outside surface, the outside surface comprises the outside opening of the through hole.

According to a twenty-sixth example, in addition to the twenty-fourth to twenty-fifth example, by the microfabrication step the seismic mass is formed on the membrane, the seismic mass vertically protruding from the membrane, in an embodiment wherein the seismic mass is comprised on an outside surface of the cover chip, the outside surface comprises the outside opening of the through hole, in an embodiment the seismic mass is surrounded by the recess.

According to a twenty-seventh example, in addition to each of the fourth and fifth aspect and the twentieth to twenty-sixth example, the method further comprising a microfabrication step for fabricating in a top surface of the base chip a vertically protruding protrusion for forming a measurement cavity that is hermetically sealed from the outside opening by the bonded connection, the top surface of the base chip comprising the terminal, optionally wherein the microfabrication step is part of the etching step, in an embodiment the protrusion comprises at least one of a contact pin comprising the terminal and a frame surrounding the terminal, the frame for bonding the base chip to the cover chip for forming the measurement cavity.

The above described third, fourth, and fifth aspect and the twentieth to twenty-seventh example can be combined with examples 1 to 19 and the first to third aspects for further details.

The invention will now be described in greater detail and in an exemplary manner using advantageous embodiments and with reference to the drawings. The described embodiments are only possible configurations in which, however, the individual features as described above can be provided independently of one another or can be omitted.

The accompanying drawings are incorporated into the specification and form a part of the specification to illustrate several embodiments of the present invention. These drawings, together with the description, serve to explain the principles of the invention. The drawings are merely for the purpose of illustrating examples of how the invention can be made and used, and are not to be construed as limiting the invention to only the illustrated and described embodiments. Furthermore, several aspects of the embodiments may form—individually or in different combinations—solutions according to the present invention. The following described embodiments thus can be considered either alone or in an arbitrary combination thereof. The described embodiments are merely possible configurations and it must be borne in mind that the individual features as described herein can be provided independently of one another or can be omitted altogether while implementing this invention. Further features and advantages will become apparent from the following more particular description of the various embodiments of the invention, as illustrated in the accompanying drawings, in which like references refer to like elements.

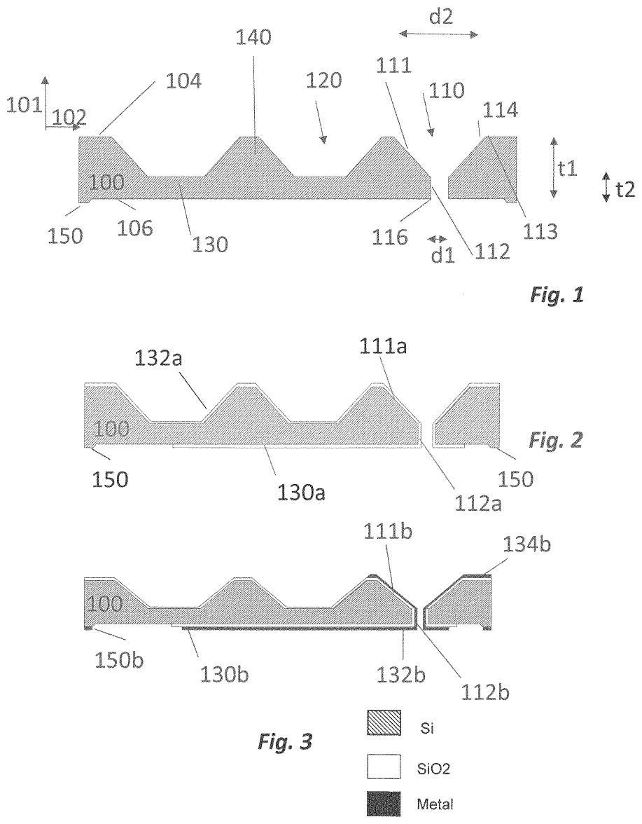

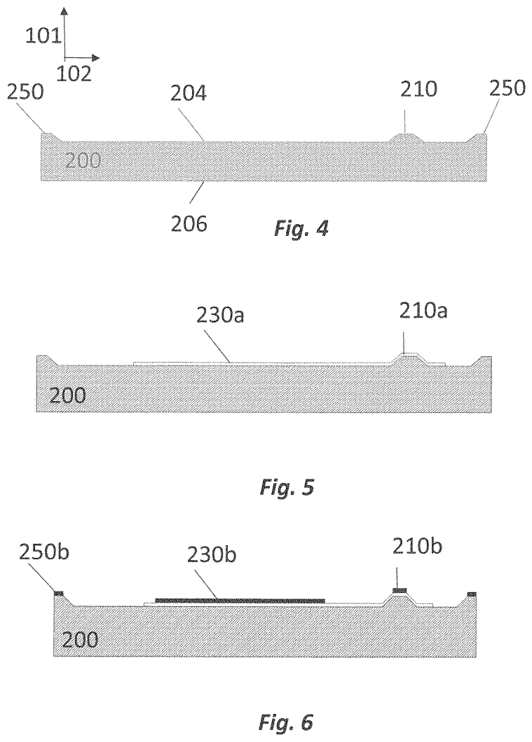

The present invention will now be explained with reference to the Figures and first with reference to FIGS. 1 and 4. FIG. 1 shows a cover chip 100 and FIG. 4 shows a base chip 200. According to the example, the cover chip 100 and the base chip 200 are structured by etching a Silicon wafer.

In more detail, the cover chip 100 comprises a vertical through hole 110 through the cover chip 100. Thus, an etched through hole surface 111, 112 connecting an outside opening 114 with diameter d2 and an opposing inside opening 116 with diameter d1 is formed.

In particular, the vertical through hole 110 with thickness t1 is formed by an anisotropic wet etch process, for forming the through hole having the shape of a frustum with frustum surface 111. Notably, the thickness t1 may be caused by the thickness of a wafer the cover chip is formed from. Further, the vertical through hole 110 can be formed by a dry etch process for forming the through hole having the shape of a prism with prism surface 112. Notably, the through hole 110 can be formed by only one etch process. According to the example, the prism shape has a thickness t2. Notably, in case of only a wet etch step t2 becomes 0 and in case of only a dry etch step, the thickness t2 becomes equal to t1.

In particular, an outside surface 104 of the cover chip 100 is etched with inductively coupled plasma (ICP) to open the TSV holes. For example, by the etching process, an incircle of the outside opening in a horizontal dimension 102 of the chip has a diameter d1 of greater than or equal to 20 μm. For example, by the dry etch process through holes with such a diameter can be created.

Alternatively, anisotropic wet etching (orientation dependent etching) can be used to form the through holes. For example, the anisotropic wet etch on a silicon wafer creates a cavity with a trapezoidal cross-section, as indicated by frustum surface 111. The bottom of the cavity is a {100} plane (using the well-established notation with 2 Miller indices), and the sides are {111} planes. In particular, wet etchants can etch crystalline materials at very different rates depending upon which crystal face is exposed. In single-crystal materials (e.g. silicon wafers), this effect can allow very high anisotropy. The term “crystallographic etching” is synonymous with “anisotropic etching along crystal planes”.

Several anisotropic wet etchants are available for silicon, all of them hot aqueous caustics. For instance, potassium hydroxide (KOH) displays an etch rate selectivity 400 times higher in <100> crystal directions than in <111> directions. EDP (an aqueous solution of ethylene diamine and pyrocatechol), displays a <100>/<111> selectivity of 17×, does not etch silicon dioxide as KOH does, and also displays high selectivity between lightly doped and heavily boron-doped (p-type) silicon.

Etching a {100} silicon surface through a rectangular hole in a masking material, for example a hole in a layer of silicon nitride, creates a pit with flat sloping {111}-oriented sidewalls and a flat {100}-oriented bottom. The {111}-oriented sidewalls have an angle to the surface of the wafer of 54.7°, i.e. the angle between the outside surface 104 and the frustum surface 111.

For example, by the wet etch process, the diameter d2 of the outside opening 114 may be greater than or equal to 250 μm. Further, the diameter d2 may be less than or equal to 1000 μm in the horizontal dimension. The range of the diameter is caused because in the example is used a wet etch step for generating the frustum surface 111.

According to an example, namely in case of only using a wet etch step, the diameter d1 of the inside opening 116 would range between greater than or equal to 5 μm and less than or equal to 200 μm in the horizontal dimension.

According to an example, namely in case of only using a dry etch process, the diameter d2 of the outside opening 114 would be greater than or equal to 70 μm and less than or equal to 500 μm in the horizontal dimension. The corresponding diameter d1 of the inside opening 116 would range between greater than or equal to 20 μm and less than or equal to 300 μm in the horizontal dimension.

Further, as shown in FIG. 1, the cover chip 100 comprises a surrounding region 113 abutting to the outside opening 114. In other words, the surrounding region 113 abuts to the through hole surface 111 and extends in a horizontal dimension 102. The cover chip 100 has a thickness t1 in a vertical dimension 101 of greater equal 150 μm. This thickness t1 is necessary that the wafer is sufficiently stable. Additionally or alternative, the thickness t1 in the vertical dimension is less than or equal to 800 μm. Depending on the requirements of the sensor, a thin cover chip thickness enables small sensor dimensions and a thick cover chip enables higher stability. The vertical dimension is perpendicular to the horizontal dimension. Thicker chips may not allow for depositing the complete through hole with a metal layer.

Notably, a combination of wet and dry etch process may be advantageous in view of a high thickness t1 because this makes a larger diameter d2 necessary. In particular, for example in case of a thick wafer, i.e. large thickness t1, t2 may be selected so that is possible to ensure sufficiency of stability of the resulting cover chip. Notably, this comes of the cost that a large aspect ratio, i.e. the ratio between thickness to diameter. Large aspect ratios makes it difficult to deposit material in the complete through hole. To ensure complete coverage, it is possible depositing material from the outside surface 104 and the inside surface 106. Further, a deepening may be formed in the inside surface resulting in the edge region 150. This deepening again may be realized by a dry etch or wet etch process.

Further, a recess 120 is comprised on the outside surface 104 of the cover chip 110, as shown in FIG. 1, the outside surface comprises the outside opening 114 of the through hole 110 and the outside surface 104 opposing an inside surface 106. In particular, the recess 120 is horizontally spaced apart from the through hole 110 and extending in the vertical dimension to form a membrane 130 in the cover chip.

Further, a test mass 140 is formed on the membrane 130, the test mass vertically protruding from the membrane 130. In particular, the test mass 140 is comprised on the outside surface 104 of the cover chip 100. Further, the test mass 140 is surrounded by the recess 120. In other words, the test mass 140 and the recess 120 forms the sensor membrane 130 with an improved force coupling through the central anvil 140 and thus a better signal linearity and a lower temperature drift in case of a force sensor.

Notably, the test mass 140 can be referred to as a proof mass or a seismic mass. Thus, the cover chip 100 can be used for an acceleration sensor.

By similar etch process as described above, the base chip 200, as shown in FIG. 4, is structured. The base chip 200 comprises a top surface 204 and an opposing bottom surface 206. The top surface 204 of the base chip 200 comprises vertically protruding protrusions, i.e. structures protruding in a vertical dimension 101. These protrusions are used for forming a measurement cavity that is hermetically sealed from the outside opening by the bonded connection, as will be later discussed in detail.

In more detail, the protrusion comprises a contact pin with a contacting region 210a for comprising a terminal, the terminal facing the inside opening of the cover chip 100. Further, the base chip 200 comprises a frame region 250 surrounding the contact pin 210, the contact pin 210 for comprising the terminal, the frame for forming a bonding region at which the base chip 200 is bonded to the cover chip 100 for forming the measurement cavity. In other words, the frame region 250 is spaced from the contact pin 210 in a horizontal dimension 102.

In a second step, as shown in FIGS. 2 and 5, the cover chip 100 and the base chip are subject to a pre-condition step. In particular, as shown in FIG. 2, the etched through hole surface 111, 112 is pre-conditioned generating a clean, in particular electrically insulating, through hole surface 111a, 112a. Similarly, as shown in FIG. 5 a contacting region 210 of the base chip for generating a clean electrically insulating contacting region 210a.

Advantageously, further regions of the cover chip 100 and the base chip 200 are pre-conditioned. In particular, as shown in FIG. 2, a membrane measurement region arranged on the inside surface 106 of the cover chip 100 is pre-conditioned for generating a clean, in particular electrically insulating, membrane measurement surface 130a. Further, an outside region arranged on the outside surface 104 of the cover chip 100 is pre-conditioned for generating a clean, electrically insulating outside surface 132a.

Further, as shown in FIG. 5, a base measurement region arranged on the top surface 204 of the base chip 200 is pre-conditioned for generating a clean, electrically insulating base measurement surface 230a.

The pre-conditioning step can comprises passivating a base material of at least one of the cover chip 100 and the base chip 200. In an embodiment, the base material comprises or consists of silicon that is passivated by oxidation. For example, an insulating layer of silicon oxide (SiO₂) is deposited and patterned.

Notably, as shown in FIG. 1, the cover chip 100 can comprise an edge region 150 surrounding the through hole 110, the edge region 150 for forming a bonding region at which the cover chip 100 is bonded to the base chip 200 for forming the measurement cavity. In other words, the edge region 150 is spaced from the through hole 110 in a horizontal dimension 102.

Notably, as shown in FIGS. 2 and 5, the edge 150 and the frame 250 are not passivated by the SiO₂ layer. Thus, these regions can used for eutectic bonding.

In a third step, as shown in FIGS. 3 and 6, the cover chip 100 and the base chip 200 are subject to a metal deposition step. In particular, as shown in FIG. 3, the metal is deposited on the electrically insulating through hole surface 111a, 112a thereby generating a vertical metal layer 111b, 112b. Thus, a VIA through the cover chip 100 is formed.

Similarly, as shown in FIG. 6, metal is deposited on the electrically insulating contacting region 210a of the base chip 200 thereby generating a horizontal metal layer 210b. Thus, a terminal on the base chip 200 is formed.

Advantageously, further regions of the cover chip 100 and the base chip 200 are coated with a metal layer. In particular, as shown in FIG. 3 the electrically insulating membrane measurement region 130a arranged on the inside surface 106 of the cover chip 100 is coated with a metal for generating a membrane electrode 130b. The membrane electrode 130b can be used as a capacitor plate for a sensor.

Further, a surrounding region 132b can be coated with a metal, the surrounding region 132b abutting and surrounding the inner opening 116 and being arranged between the membrane electrode 130b and the vertical metal layer 112b. The surrounding region 132b can be used to increase the diffusion region for the thermocompression bond. Further, the surrounding region 132b may electrically contact the membrane electrode 130b for generating an electrical contact.

Further, an outer region 134b can be coated with a metal, the outer region 134b for forming an outer terminal for connecting for example with an evaluation unit for analyzing sensed signals sensed by the membrane electrode 130b.

Further, as shown in FIG. 6, the electrically insulating base measurement region arranged on the top surface 204 of the base chip 200 is coated with a metal layer for generating a base electrode 230b.

Further, as shown in FIGS. 3 and 6, the edge region 150 is metallized with an edge layer 150b and the frame region 250 is metallized with a frame layer 250b.

Notably, depositing metal, coating with metal, or metallization of regions can be executed by one process step. For example, the membrane metal layer is metalized in the same step of depositing the vertical metal layer forming the VIA. Additionally or alternatively, depositing the base metal layer is executed in the same step of depositing the horizontal metal layer forming the terminal.

Advantageously each of the vertical metal layer and the horizontal metal layer comprise a same metal. In an embodiment, the vertical metal layer and the horizontal metal layer comprise at least one of gold, aluminum, and copper. Further, the other mentioned regions may comprise or consist of the same material or different materials.

In other words, the process step illustrated by FIGS. 3 and 6 enables metallizing a surface of the base plate 200 and both surface of the cover plate 100. For example, gold is also deposited and patterned on the edge region 150 and the frame region 250 of a measurement cavity for subsequent eutectic bonding the cover plate 100 to the base plate 200, and the insulated sidewall of the VIA is also metallized. Thus, an insulated capacitive sensor electrode, the insulated bonding area of the TSVs and a metallized chip edge without insulation are structured in one step (FIGS. 3 and 6). Notably, as shown in FIGS. 3 and 6, the edge region 150 and the frame region 250 are directly coated with metal. This may be done by not coating the region with further layers such as an adhesive layer or a diffusion layer or by removing such layers.

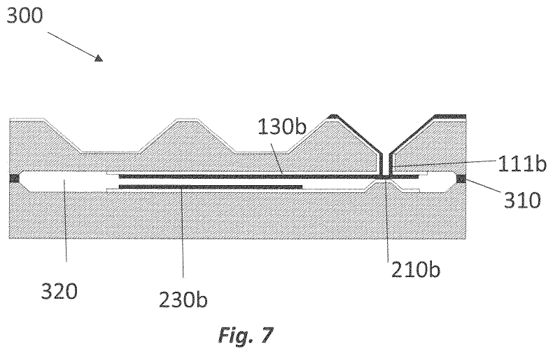

Further, as shown in FIG. 7, the cover chip 100 is aligned with the base plate 200. In particular, the vertical metal layer 112b of the VIA is aligned with the horizontal metal layer 210b of the terminal. Then, a thermocompression bonding of the vertical metal layer of the VIA to the horizontal metal layer of the terminal in initiated for forming a bonded connection. The bonded connection hermetically seals the contact between the VIA and the terminal.

In more detail, in a bonding oven, the base chip and the cover chip are heated 30° C. over eutectic temperature with a hold-time, which is long enough for the intermetallic eutectic diffusion process, in an embodiment under vacuum and with a contact force, which is great enough to create a thermocompression bond, so that they are bonded together by thermocompression bonding.

As shown in FIG. 7, by aligning the cover chip 100 with the base plate 200, the edge layer 150b is aligned with the frame layer 250b thereby forming a eutectic bonding region 310. Thus, during the thermocompression bonding additionally a eutectic bonding occurs. Thus, a measurement cavity 320 is hermetically sealed.

In other words, as shown in FIG. 7, the processes described with reference to FIGS. 1 to 6 can be used to form a sensor 300. The sensor 300 comprises a housing formed by the base chip and the cover chip. The housing enclosing the hermetically sealed measurement cavity 320, wherein the measurement cavity 320 comprises the inside surface of the cover chip and the opposing top surface of a base chip, the inside surface comprising the membrane electrode 130b and the top surface comprising a base electrode 230b, the membrane electrode 130b and the base electrode 230b for forming a sensing capacitance.

Further, as shown in FIG. 7 the sensor comprises a device for contacting the membrane electrode 130b by the terminal. A device the base electrode, e.g. by a second terminal.

As shown in FIGS. 1 to 7, the terminal is formed by a first horizontal metal 210b layer and contacts the vertical metal layer 112b of the VIA through the housing, wherein horizontal metal layer 210b and the vertical metal layer forming a first hermetically sealed contact, namely by being bonded together using a process of thermocompression bonding.

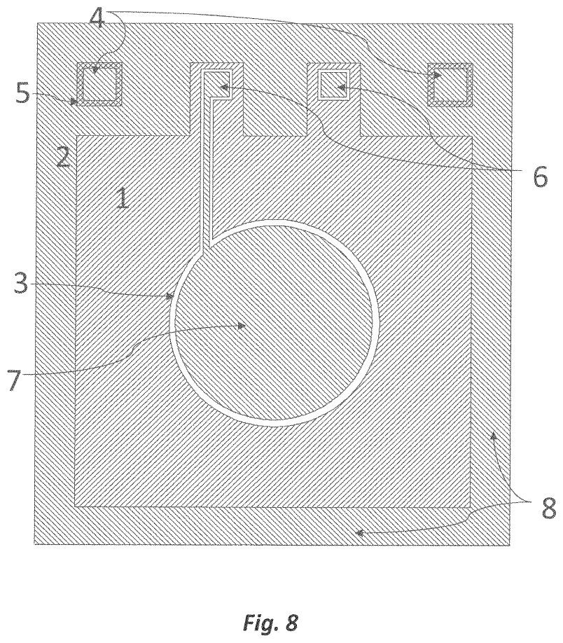

As shown with reference to FIG. 8, a top view of the base plate, the sensor can comprise a second terminal for contacting the electrodes and third and fourth terminals. In more detail, the base material 1 of the base plate 100 is for example silicon. Metal can be coated in the metal coated regions 2, for example the frame region 250, the metal may be gold, aluminum, or a combination of both, for example for the eutectic bonding connection aluminum may be used and the horizontal metal layer for forming the terminal and the vertical metal layer may comprise gold. Further, an isolation layer 3, e.g. the electrically insulating base measurement surface 230a, can be provided, and mass or ground contacts 4 at the TSV connection surface can be provided. Further, the base chip can comprise electrically conductive connecting device 5 for connecting a ground lead making conductive connection with the material of the base plate and with the connected material of the cover plate. Further, electrode contacts 6 can be formed by the TSV connecting surface, i.e. the vertical metal layer 111b. The base electrode 7 (230b in FIGS. 6 and 7) has a circular shape and is formed by an electrode. Notably, the electrode may have any other shape than a circular shape. The frame region 8 (the frame region 250 in FIG. 4) is used for the eutectic bond of the base chip to the cover chip.

As described above, the cover chip comprises an eutectic bonding 310 that is formed by eutectic bonding an edge region arranged on the inside surface of the cover chip and surrounding the membrane electrode to a frame region arranged on the top surface of the base chip and surrounding the base electrode for forming an eutectic bond, the eutectic bond hermetically sealing the measurement cavity 320 from the outside. In other words, the edge layer 150b shown in FIG. 3 is bonded to the frame layer 250b shown in FIG. 6.

Eutectic bonding has the advantage that the base and cover chips are fused together and thus are electrically and mechanically connected. Hence, a third electrode is connected to the entire structure material and forms a Faraday cage around the measuring electrodes.

Moreover, an operating temperature of up to 350° C. can be achieved with Au as bonding material. To increase the operating temperature up to 500° C., aluminum can be used instead of gold. The electrodes are routed to the TSVs contact surfaces via a conductive path. Bonding seals the TSVs contact areas on both chips together, bringing the electrodes into contact with the contact pads (134b) on the outer surface of the cover plate and achieving the hermetic seal. Compared to most technologies, no electroplating or conductive adhesive is required to fill the TSVs with conductive materials. In addition, wafer-level bonding is conceivable through the use of TSVs. The resulting distance between the capacitive electrodes after bonding is equal to or less than 10 μm. The value can depend on the membrane size and the thickness. Such a distance ensures an almost displacement-free force measurement. Moreover, this small distance between the electrodes increases the sensitivity of the sensor, as the change in capacitance is 100% at a distance equal to half the electrode spacing.

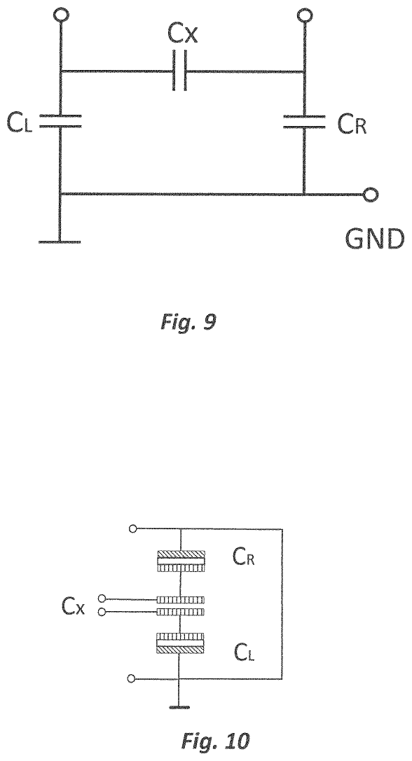

In the example described with reference to FIGS. 1 to 7, the cover chip 100 and the base chip 200 comprise or consist of a conducting material thereby forming a Faraday cage for protecting the sensing capacitance against external interference. In particular, FIGS. 9 and 10 show a simplified electrical equivalent circuit diagram of the sensor. By fusing together at their outer edge the base chip and the cover chip, the chips are electrically and mechanically connected together. Thus, a third electrode is connected to the entire structural material and forms a Faraday cage around the measuring electrodes. In addition, the entire structure with the measuring electrodes forms a large parasitic capacitance that can be brought to a defined potential, as shown in FIGS. 9 and 10.

Thus, the sensor shown in FIG. 7 is particularly suitable as a force sensor or an absolute pressure sensor.

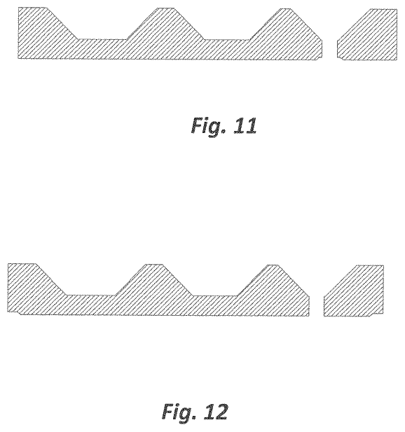

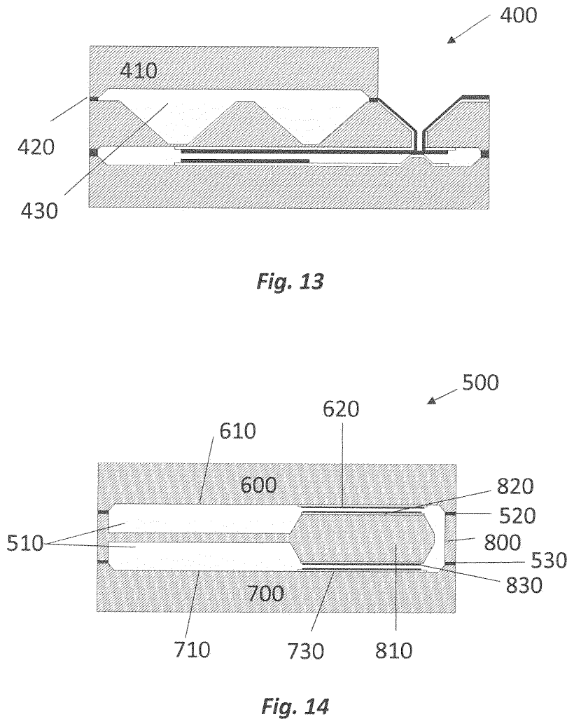

Further alternatives for the cover plate are shown with reference to FIGS. 11 to 12. In particular, FIGS. 11 to 12 show example to additionally etch the inside surface of the cover plate. For example, the cover chip can comprise a membrane deepening as shown in FIG. 1. Further, the cover chip can comprise a through-hole deepening as shown in FIG. 11. Finally, the cover chip can comprise an edge deepening as shown in FIG. 13.

In particular, the membrane deepening is horizontally spaced apart from the inside opening to form a membrane in the cover chip, the through-hole deepening is horizontally aligned with the inside opening to reduce a thickness of the cover chip in a region of the VIA, and the edge deepening is surrounding the inside opening, the edge deepening for bonding the cover chip to the base chip.

In particular, FIG. 1 shows a combination of the membrane deepening and the through-hole deepening.

Further, the sensor of FIG. 7 may be further modified to form an acceleration senor as shown in FIGS. 13 and 14. For example, the acceleration sensor 400 of FIG. 13 comprises the sensor shown in FIG. 7 and additionally comprises a protecting chip 410. The protecting chip 410 is connected by a eutectic bonding 420 to a second edge region arranged on an outside surface of the cover chip, the outside surface opposing the inside surface, and surrounding the membrane for forming a hermetically sealed protecting cavity 430.

For a description of further parts of the acceleration sensor 400 is referred to the above description of FIGS. 1 to 12. In particular, the acceleration sensor 400 can, but does not have to, comprise the hermetically sealed contact between a vertical electric connection (VIA) through a cover chip and a terminal on a base chip. The general idea is that by two bonding process a sealed cavity is fabricated, namely in the examples disclosed in FIGS. 1 to 7 by the eutectic bonding and the thermocompression bonding and in the examples disclosed in FIGS. 13 and 14 by two eutectic bonding steps.

An alternative of an acceleration sensor is shown in FIG. 14. Similar to the sensor shown in FIG. 13, the acceleration sensor 500 comprises a first and second bonding. Alternatively, the seismic mass is arranged in a measurement cavity.

In more detail, the acceleration sensor comprises a housing hermetically sealing a measurement cavity 510. The measurement cavity 510 comprises a first inside surface 610 of a cover chip 600 and an opposing top surface of an intermediate chip 800, and a second inside surface 710 of a base chip 700 and an opposing bottom surface of the intermediate chip 800. The cover chip 600 and the base chip 700 can be realized as the cover chip described with reference to FIGS. 1 to 6.

In more detail, the first inside surface 610 comprises a first inside electrode 620 and the top surface comprises a first intermediate electrode 820. The first inside electrode 620 and the first intermediate electrode 820 form a first sensing capacitance.

Further, the second inside surface 710 comprises a second inside electrode 730 and the bottom surface comprises a second intermediate electrode 830, the second inside electrode 730 and the second intermediate 830 electrode for forming a second sensing capacitance.

The first sensing capacitance is contacted by a contact arrangement having, for example, a first and a second terminal and the second sensing capacitance is contacted by a contact arrangement having for example a third and a fourth terminal. In particular, the hermetically sealed VIA as described above with FIGS. 1 to 7 can be used for contacting the sensing capacitances. For a description is referred to the above description.

Further, a first eutectic bonding 520 connects a first edge region arranged on the first inside surface 610 of the cover chip 600 and surrounding the first inside electrode 620 to a first frame region arranged on the top surface of the intermediate chip 800 and surrounding the first intermediate electrode 820.

Further, a second eutectic bond 530 connects a second edge region arranged on the second inside surface 710 of the base chip 700 and surrounding the second inside electrode 730 to a second frame region arranged on the bottom surface of the intermediate chip 800 and surrounding the second intermediate electrode 830.

With regard to the eutectic bonding is referred to the above description of FIG. 7. The first and second eutectic bond 520 and 530 hermetically seal the measurement cavity 510 from the outside.

Further, the intermediate chip 800 comprises a tongue holding a deflectable seismic mass 810 between the top electrode 820 and the bottom electrode 830 for changing the capacitance of the first and second sensing capacitance.

The present disclosure provides an economic fabrication process of a VIA, a VIA that hermetically seals even at elevated temperatures, and a VIA that can also reach greater depths.

The VIA of the present disclosure has a particular good sealing quality, namely that the connection of the VIA to a terminal is air tight, i.e. is hermetically sealing.

The present disclosure also provides an economic fabrication process of a sealed cavity, and a sealed connection to the cavity. Further, the sensor can be protected from the measurement medium. The present disclosure reduces the complexity in fabricating the cavity and avoids stresses in the material, e.g. cause by high temperatures. Further, the present disclosure overcomes drawbacks based on parasitic capacitances.

1. A method for creating a sensor, comprising:
generating in a housing a measurement cavity that is hermetically sealed, the measurement cavity is formed by an inside surface of a cover chip and an opposing top surface of a base chip, the inside surface has a membrane electrode and the top surface has a base electrode, the membrane electrode and the base electrode form a sensing capacitance;
contacting the membrane electrode with a first terminal and contacting the base electrode with a second terminal,
the first terminal is a first horizontal metal layer and contacts a first vertical metal layer of a first vertical electrical connection (VIA) through the housing, the first horizontal metal layer and the first vertical metal layer forming a first hermetically sealed contact, and/or
the second terminal is a second horizontal metal layer and contacts a second vertical metal layer of a second VIA through the housing, the second horizontal metal layer and the second vertical metal layer forming a second hermetically sealed contact; and
eutectic bonding an edge region arranged on the inside surface of the cover chip and surrounding the membrane electrode to a frame region arranged on the top surface of the base chip and surrounding the base electrode for forming a eutectic bond, the eutectic bond hermetically sealing the measurement cavity from an outside.

2. The method of claim 1, wherein the first hermetically sealed contact and/or the second hermetically sealed contact is formed by:
etching a vertical through hole through the cover chip to form an etched through hole surface connecting an outside opening and an inside opening opposing the outside opening, the inside opening facing the first terminal and/or the second terminal on the base chip;
pre-conditioning the etched through hole surface to generate an electrically insulating through hole surface and pre-conditioning a contacting region of the base chip to generate an electrically insulating contacting region;
depositing a vertical metal layer on the electrically insulating through hole surface to generate the first VIA and/or the second VIA through the cover chip and depositing the first horizontal metal layer and/or the second horizontal metal layer on the electrically insulating contacting region to generate the first terminal and/or the second terminal on the base chip; and
thermocompression bonding the vertical metal layer of the first VIA and/or the second VIA to the first horizontal metal layer of the first terminal and/or the second horizontal metal layer of the second terminal to form a bonded connection, the bonded connection hermetically sealing a contact between the first VIA and/or the second VIA and the first terminal and/or the second terminal.

3. The method of claim 1, further comprising:
pre-conditioning a membrane measurement region arranged on the inside surface of the cover chip to generate an electrically insulating membrane measurement surface and pre-conditioning a base measurement region arranged on the top surface of the base chip to generate an electrically insulating base measurement surface; and
depositing a membrane metal layer on the electrically insulating membrane measurement surface to generate a membrane electrode of the sensor and depositing a base metal layer on the electrically insulating base measurement surface to generate a base electrode.

4. The method of claim 1, wherein the cover chip and the base chip include a conducting material forming a Faraday cage protecting the sensing capacitance against external interference, the cover chip has at least one of the first VIA and the second VIA.

5. A method for creating an acceleration sensor, comprising:
generating in a housing a measurement cavity that is hermetically sealed, the measurement cavity is formed by an inside surface of a cover chip having a membrane and an opposing top surface of a base chip, the inside surface having a membrane electrode formed on the membrane and the top surface having a base electrode, the membrane electrode and the base electrode form a sensing capacitance, the membrane has a deflectable seismic mass for changing a capacitance of the sensing capacitance;
contacting the membrane electrode with a first terminal;
contacting the base electrode with a second terminal;
eutectic bonding a first edge region arranged on the inside surface of the cover chip and surrounding the membrane to a frame region arranged on the top surface of the base chip and surrounding the base electrode for forming a eutectic bond, the eutectic bond hermetically sealing the measurement cavity from an outside; and
eutectic bonding a second edge region arranged on an outside surface of the cover chip, the outside surface opposing the inside surface, and surrounding the membrane to a protecting chip to form a hermetically sealed protecting cavity.

6. A method for creating an acceleration sensor, comprising:
generating in a housing a measurement cavity that is hermetically sealed, the measurement cavity is formed by a first inside surface of a cover chip and an opposing top surface of an intermediate chip, and a second inside surface of a base chip and an opposing bottom surface of the intermediate chip, the first inside surface has a first inside electrode and the top surface has a first intermediate electrode, the first inside electrode and the first intermediate electrode form a first sensing capacitance, the second inside surface has a second inside electrode and the bottom surface has a second intermediate electrode, the second inside electrode and the second intermediate electrode form a second sensing capacitance;
contacting the first sensing capacitance with at least one first terminal;
contacting the second sensing capacitance with at least one second terminal;
eutectic bonding a first edge region arranged on the first inside surface of the cover chip and surrounding the first inside electrode to a first frame region arranged on the top surface of the intermediate chip and surrounding the first intermediate electrode to form a first eutectic bond; and
eutectic bonding a second edge region arranged on the second inside surface of the base chip and surrounding the second inside electrode to a second frame region arranged on the bottom surface of the intermediate chip and surrounding the second intermediate electrode to form a second eutectic bond, the first eutectic bond and the second eutectic bond hermetically seal the measurement cavity from an outside, the intermediate chip has a tongue holding a deflectable seismic mass between the top electrode and the bottom electrode for changing a capacitance of the first sensing capacitance and the second sensing capacitance.

7. The method of claim 6, wherein the first terminal is connected to a first VIA forming a first hermetically sealed contact and/or the second terminal is connected to a second VIA forming a second hermetically sealed contact, a method for fabricating the first hermetically sealed contact and/or the second hermetically sealed contact includes:
etching a vertical through hole through the cover chip to form an etched through hole surface connecting an outside opening and an inside opening opposing the outside opening, the inside opening facing the first terminal and/or the second terminal on the base chip;
pre-conditioning the etched through hole surface to generate an electrically insulating through hole surface and pre-conditioning a contacting region of the base chip to generate an electrically insulating contacting region;
depositing a vertical metal layer on the electrically insulating through hole surface to generate the first VIA and/or the second VIA through the cover chip and depositing a horizontal metal layer on the electrically insulating contacting region for generating the first and/or second terminal on the base chip; and
thermocompression bonding the vertical metal layer of the first VIA and/or the second VIA to the horizontal metal layer of the first terminal and/or the second terminal to form a bonded connection, the bonded connection hermetically sealing contact between the terminal and the first VIA and/or the second VIA.

8. The method of claim 7, wherein an incircle of the outside opening has a diameter of greater than or equal to 70 μm and/or less than or equal to 1000 μm.

9. The method of claim 7, wherein a surrounding region abutting the outside opening has a thickness in a vertical dimension of greater equal 150 μm and/or less than or equal to 800 μm.

10. The method of claim 7, wherein the pre-conditioning step includes passivating a base material of at least one of the cover chip, the base chip, the intermediate chip, and the protecting chip.

11. The method of claim 7, wherein each of the vertical metal layer and the horizontal metal layer are a same metal.

12. The method of claim 7, further comprising a microfabrication step for fabricating a recess in the cover chip, the recess being horizontally spaced from the vertical through hole and extending in a vertical dimension to form a membrane in the cover chip.

13. The method of claim 12, wherein the recess is on an outside surface that includes the outside opening of the vertical through hole.

14. The method of claim 12, wherein, by the microfabrication step, the deflectable seismic mass is formed on the membrane, the seismic mass vertically protruding from the membrane, the seismic mass is on an outside surface of the cover chip that includes the outside opening of the vertical through hole, the seismic mass is surrounded by the recess.

15. The method of claim 7, further comprising a microfabrication step for fabricating in a top surface of the base chip a vertically protruding protrusion forming a measurement cavity that is hermetically sealed from the outside opening by the bonded connection, the top surface of the base chip has the terminal.
